(19) United States
(12) Patent Application Publication
(10) Pub. No.: US 2026/0018227 A1
(43) Pub. Date: Jan. 15, 2026

(54) MEMORY WITH COMMAND-ADDRESS INPUT BUFFER CONTROL, AND ASSOCIATED SYSTEMS, DEVICES, AND METHODS

(71) Applicant: Micron Technology, Inc., Boise, ID (US)

(72) Inventor: Jaeil Kim, Boise, ID (US)

(21) Appl. No.: 19/260,118

(22) Filed: Jul. 3, 2025

Related U.S. Application Data
(60) Provisional application No. 63/671,031, filed on Jul. 13, 2024.

(51) Int. Cl. G11C 29/12; G11C 11/4093; G11C 29/14

(52) U.S. Cl. CPC G11C 29/1201; G11C 11/4093; G11C 29/14

(57) ABSTRACT

Memory with command-address input buffer control is disclosed herein. In one embodiment, a memory device includes a plurality of command-address input buffers configured to receive a corresponding plurality of command-address signals of a command signal. The command signal can be received at one or more external terminals of the memory device. The memory device can further include input buffer control circuitry configured to disable one or more command-address input buffers of the plurality of command-address input buffers at times when one or more command-address signals of the plurality of command-address signals that correspond to the one or more command-address input buffers are not used. For example, the input buffer control circuitry can disable the one or more command-address input buffers based at least in part on the memory device being outside an idle mode of operation or a connectivity test being disabled while a mirror function is enabled or disabled.

### CROSS-REFERENCE TO RELATED APPLICATION(S)

The present application claims priority to U.S. Provisional Patent Application No. 63/671,031, filed Jul. 13, 2024, the disclosure of which is incorporated herein by reference in its entirety.

### TECHNICAL FIELD

The present disclosure is generally related to semiconductor devices. For example, several embodiments of the present technology relate to memory devices that selectively disable command-address (CA) input buffers (e.g., to reduce power consumption), such as when the CA input buffers are not being used.

### BACKGROUND

An electronic apparatus (e.g., a processor, a memory device, a memory system, or a combination thereof) can include one or more semiconductor circuits configured to store and/or process information. For example, the apparatus can include a memory device, such as a volatile memory device, a non-volatile memory device, or a combination device. Memory devices, such as dynamic random-access memory (DRAM), NAND memory, and/or high-bandwidth memory (HBM), can utilize electrical energy to store and access data.

With technological advancements in embedded systems and increasing applications, the market is continuously looking for faster, more efficient, and smaller devices. To meet market demands, the semiconductor devices are being pushed to the limit with various improvements. Improving devices, generally, may include increasing circuit density, increasing circuit capacity, increasing operating speeds (or otherwise reducing operational latency), increasing reliability, increasing data retention, reducing power consumption, increasing energy efficiency, or reducing manufacturing costs, among other metrics.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but are for explanation and understanding only.

FIG. 1A is a block diagram schematically illustrating a memory system configured in accordance with various embodiments of the present technology.

FIG. 1B is a block diagram schematically illustrating a memory device configured in accordance with various embodiments of the present technology.

FIG. 2 is a partially schematic circuit diagram of input buffer control circuitry configured in accordance with various embodiments of the present technology.

FIGS. 3A and 3B are flow diagrams illustrating methods of controlling one or more input buffers in accordance with various embodiments of the present technology.

FIG. 4 is a partially schematic circuit diagram of input buffer control circuitry configured in accordance with various embodiments of the present technology.

FIG. 5 is a flow diagram illustrating a method of controlling one or more input buffers in accordance with various embodiments of the present technology.

FIG. 6 is a partially schematic circuit diagram of input buffer control circuitry configured in accordance with various embodiments of the present technology.

FIG. 7 is a flow diagram illustrating a method of controlling one or more input buffers in accordance with various embodiments of the present technology.

FIG. 8 is a block diagram of a system having a memory device configured in accordance with embodiments of the present technology.

### DETAILED DESCRIPTION

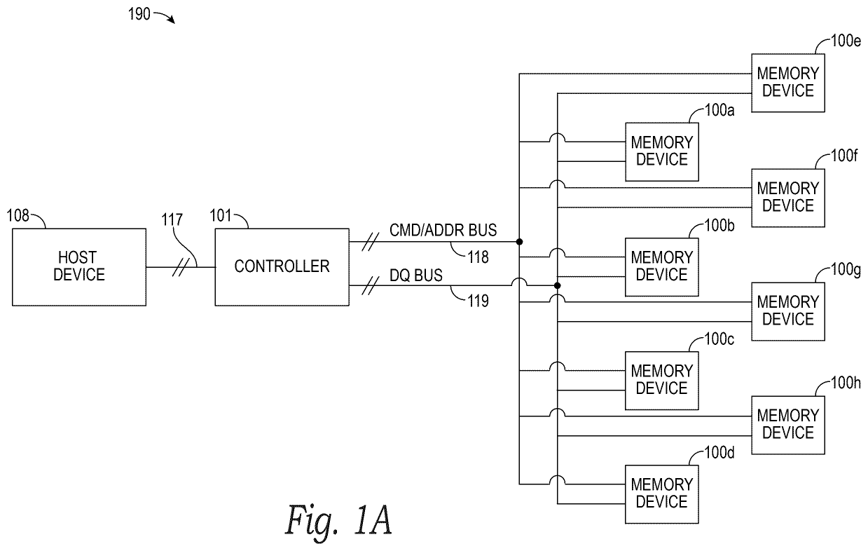

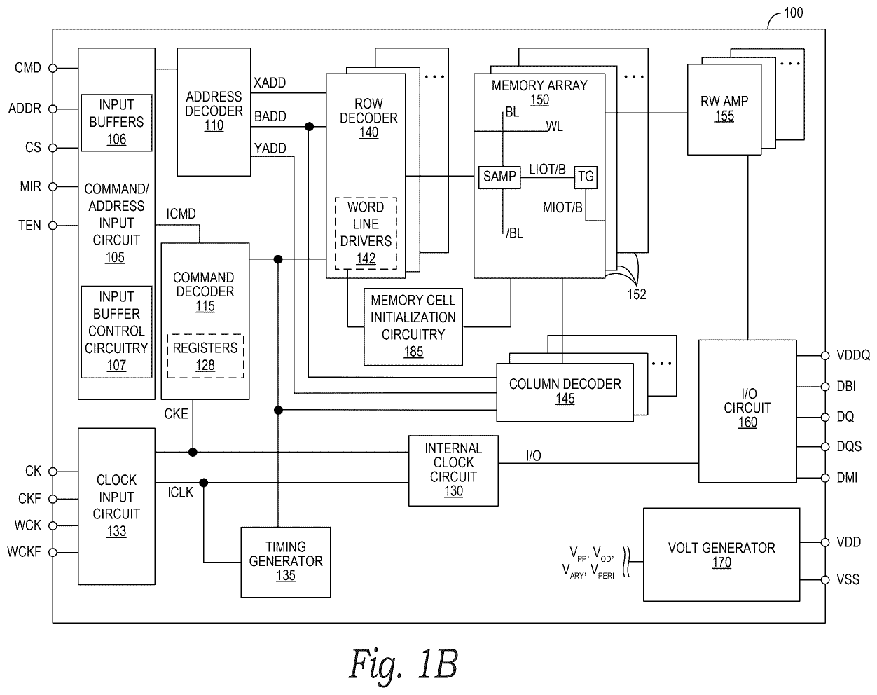

As discussed in greater detail below, the technology disclosed herein relates to memory devices with input buffer control. For example, several embodiments of the present technology described herein are directed to memory devices that employ input buffer control circuitry configured to selectively disable one or more input buffers when corresponding signals received by the memory device are not being used. A person skilled in the art will understand that the technology may have additional embodiments and that the technology may be practiced without several of the details of the embodiments described below with reference to FIGS. 1A-8.

In the illustrated embodiments below, memory devices and systems are primarily described in the context of devices incorporating DRAM storage media. Memory devices configured in accordance with other embodiments of the present technology, however, can include other types of memory devices and systems incorporating other types of storage media, including PCM, SRAM, FRAM, RRAM, MRAM, read only memory (ROM), crasable programmable ROM (EPROM), electrically crasable programmable ROM (EEROM), ferroelectric, magnetoresistive, and other storage media, including non-volatile, flash (e.g., NAND and/or NOR) storage media.

Many memory devices include command terminals and corresponding input buffers for receiving command signals sent to the memory devices from, for example, memory controllers or other host devices operably coupled to the memory devices. Each command signal is commonly received by a memory device as a set of command-address signals. For example, in double data rate fifth-generation (DDR5) DRAM devices, each command signal is commonly received as a set of fourteen different command-address signals CA0-CA13. Each of the command-address signals can be transmitted with a corresponding value (e.g., a logical high state, a logical low state), and the combination of values across all or a subset of the command-address signals can help the memory device identify a specific command and/or specific information included in the command signal.

Not every command-address signal, however, must be used with every command signal sent to the memory devices. For example, in many memory devices, command-address signal CA12 is commonly used as a slice address in 3DS implementations, is commonly used as row address R16 in an active (activate) mode of a memory device, is commonly used as mode register address MRA7 for mode register read commands and mode register write commands, is commonly used as address value OP7 for setting internal reference voltages using V_{REFCA} commands and V_{REFCS} command, and is commonly swapped with command-address signal CA13 when a mirror function of the memory device is enabled. Therefore, although commonly transmitted with each command signal, command-address CA12 can be unused in non-3DS implementations (e.g., unused in planar memory devices), in active modes of memory devices with memory densities of 16 Gbit or less in which row address R16 is not used, and/or when a mirror function of a memory device is enabled.

As another example, command-address signal CA13 is commonly used as a slice address in three-dimensional stack (3DS) implementations of DRAM devices, is commonly used as row address R17 in an active (activate) mode of a memory device, and is commonly swapped with command-address signal CA12 when a mirror function of the memory device is enabled. Therefore, although commonly transmitted with each command signal, command-address signal CA13 can be unused in non-3DS implementations, in active (activate) modes of memory devices with memory densities of 16 Gbit or less in which row address R17 is not used, and/or when a mirror function of the memory devices is disabled.

In many memory devices, as a command-address signal is received at a memory device, the command-address signal is temporarily held by a corresponding command-address input buffer of the memory device. The command-address input buffer, when enabled, consumes current/power. Thus, in memory systems in which the command-address signal is transmitted to the memory devices even when the command-address signal is not being used, enabling (or keeping enabled) the corresponding command-address input buffer to receive the unused command-address signal constitutes a waste of current/power, which is exacerbated during high-frequency operations of the memory device.

To address these concerns, the present technology is generally directed to memory devices with input buffer control. For example, several embodiments of the present technology described below are directed to memory devices (and associated methods) with input buffer control circuitry. The input buffer control circuitry can be used to selectively disable input buffers at times when corresponding input signals are not being used. For example, the input buffer control circuitry can be used to selectively disable input buffers based at least in part on (i) an operating mode of the memory device and (ii) a memory density of the memory device, a connectivity testmode enable signal, and/or a mirror function enable signal (e.g., in addition to or instead of a chip select signal). As a specific example, input buffer control circuitry of the present technology can be used to (a) disable a first command-address input buffer (e.g., corresponding to command-address signal CA12) and a second command-address input buffer (e.g., corresponding to command-address signal CA13) of a memory device when the memory device is outside an idle (precharge) mode of operation; (b) disable the first command-address input buffer when the memory device is in the idle mode of operation and a mirror function of the memory device is enabled; and/or (c) disable the second command-address input buffer when the memory device is in the idle mode of operation and the mirror function of the memory device is disabled.

As another specific example, input buffer control circuitry of the present technology can be used to (a) disable a first command-address input buffer (e.g., corresponding to command-address signal CA12) and a second command-address input buffer (e.g., corresponding to command-address signal CA13) of a memory device when a connectivity testmode of the memory device is enabled; (b) disable the first command-address input buffer when the connectivity testmode of the memory device is disabled and a mirror function of the memory device is enabled; and/or (c) disable the second command-address input buffer when the connectivity test of the memory device is disabled and the mirror function of the memory device is disabled. As still another example, input buffer control circuitry of the present technology can be used to disable a first command-address input buffer (e.g., corresponding to command-address signal CA12) and a second command-address input buffer (e.g., corresponding to command-address signal CA13) of a memory device when a connectivity test of the memory device is enabled.

As yet other examples, input buffer control circuitry of the present technology can be used to disable a first command-address input buffer (e.g., corresponding to command-address signal CA12) and a second command-address input buffer (e.g., corresponding to command-address signal CA13) of a memory device in a 3DS implementation (1) when a 3DS mode of the memory device is enabled and a slice address does not correspond to a slice layer of the memory device and/or (2) when corresponding command-address signals are used to provide row addresses that are used only for memory densities greater than the memory density of the memory device.

By disabling (or turning off) input buffers at times when corresponding input signals are not used, the present technology is expected to reduce, minimize, or eliminate unnecessary current/power consumption by the input buffers. In turn, the present technology is expected to reduce all types of IDD current consumption of the memory device except for refresh, power-down, and maximum power saving mode. In addition, the current/power savings realized by the present technology is expected to be particularly beneficial during high-frequency operations of the memory device during which current consumption of enabled input buffers typically increases.

FIG. 1A is a block diagram schematically illustrating a memory system 190 (e.g., a dual in-line memory module (DIMM), such as a regular DIMM or a three-dimensional stack (3DS) DIMM) configured in accordance with various embodiments of the present technology. In the illustrated embodiment, the memory system 190 includes a module or rank of memory devices 100 (identified individually as memory devices 100a-100h in FIG. 1A), a controller 101, and a host device 108. In some embodiments, the memory devices 100 can be DRAM memory devices. For example, one or more of the memory devices 100 can be double data rate fifth-generation (DDR5) memory devices or another generation (e.g., DDR4, DDR3, etc.) memory devices. Although illustrated with a single module/rank of eight memory devices 100 in FIG. 1A, the memory system 190 can include a greater or lesser number of memory devices 100 and/or memory modules/ranks in other embodiments of the present technology. Well-known components of the memory system 190 have been omitted from FIG. 1A and are not described in detail below so as to avoid unnecessarily obscuring aspects of the present technology.

The memory devices 100 can be connected to one or more electronic devices that are capable of utilizing memory for temporary or persistent storage of information, or a component thereof. For example, one or more of the memory devices 100 can be operably connected to one or more host devices. As a specific example, the memory devices 100 of the memory system 190 illustrated in FIG. 1A are connected to a host device 101 (hereinafter referred to as a “memory controller 101” or a “control circuit 101”) and to a host device 108.

The memory devices 100 of FIG. 1A are operably connected to the memory controller 101 via a command/address (CMD/ADDR) bus 118 and a data (DQ) bus 119. As described in greater detail below with respect to FIG. 1B, the CMD/ADDR bus 118 and the DQ bus 119 can be used by the memory controller 101 to communicate commands, memory addresses, and/or data to the memory devices 100. In response, the memory devices 100 can execute commands received from the memory controller 101. For example, in the event a write command is received from the memory controller 101 over the CMD/ADDR bus 118, the memory devices 100 can receive data from the memory controller 101 over the data DQ bus 119 and can write the data to memory cells corresponding to memory addresses received from the memory controller 101 over the CMD/ADDR bus 118. As another example, in the event a read command is received from the memory controller 101 over the CMD/ADDR bus 118, the memory devices 100 can output data to the memory controller 101 over the data DQ bus 119 from memory cells corresponding to memory addresses received from the memory controller 101 over the CMD/ADDR bus 118.

The host device 108 of FIG. 1A may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device 108 may be a networking device (e.g., a switch, a router, etc.); a recorder of digital images, audio, and/or video; a vehicle; an appliance; a toy; or any one of a number of other products. In one embodiment, the host device 108 may be connected directly to one or more of the memory devices 100 (e.g., via a communications bus of signal traces (not shown)). Additionally, or alternatively, the host device 108 may be indirectly connected to one or more of the memory device 100 (e.g., over a networked connection or through intermediary devices, such as through the memory controller 101 and/or via a communications bus 117 of signal traces).

FIG. 1B is a block diagram schematically illustrating a memory device 100 configured in accordance with various embodiments of the present technology. In some embodiments, the memory device 100 may include a memory die (e.g., a single memory die, only one memory die) or multiple memory dies. In embodiments in which the memory device 100 includes multiple memory dies, the memory dies may be arranged in a stack (e.g., a three-dimensional stack (3DS)), may be laterally offset from one another, or may positioned in another suitable arrangement.

The memory device 100 may include an array of memory cells, such as memory array 150. The memory array 150 may include a plurality of banks (e.g., banks 0-15 in the example of FIG. 1B), and each bank may include a plurality of word lines (WL), a plurality of bit lines (BL), and a plurality of memory cells (e.g., m×n memory cells) arranged at intersections of the word lines (e.g., m word lines, which may also be referred to as rows) and the bit lines (e.g., n bit lines, which may also be referred to as columns). Each word line of the plurality may be coupled with a corresponding word line driver (WL driver) configured to control a voltage of the word line during memory operations.

Memory cells can include any one of a number of different memory media types, including capacitive, phase change, magnetoresistive, ferroelectric, or the like. In some embodiments, a portion of the memory array 150 may be configured to store ECC information, such as ECC parity bits (ECC check bits) or codes. The selection of a word line WL may be performed by a row decoder 140, and the selection of a bit line BL may be performed by a column decoder 145. Sense amplifiers (SAMP) may be provided for corresponding bit lines BL and connected to at least one respective local I/O line pair (LIOT/B), which may in turn be coupled to at least one respective main I/O line pair (MIOT/B), via transfer gates (TG), which can function as switches. The memory array 150 may also include plate lines and corresponding circuitry for managing their operation.

The memory device 100 may employ a plurality of external terminals that include command and address terminals coupled to a command bus and an address bus (e.g., the CMD/ADDR bus 118 of FIG. 1A) to receive command signals CMD and address signals ADDR, respectively. The memory device may further include a chip select terminal to receive a chip select signal CS, clock terminals to receive clock signals CK and CKF, data clock terminals to receive data clock signals WCK and WCKF, data terminals DQ, RDQS, DBI (for data bus inversion function), and DMI (for data mask inversion function), power supply terminals VDD, VSS, and VDDQ.

The power supply terminals may be supplied with power supply potentials VDD and VSS. These power supply potentials VDD and VSS can be supplied to an internal voltage generator circuit 170. The internal voltage generator circuit 170 can generate various internal potentials VPP, VOD, VARY, VPERI, and the like based on the power supply potentials VDD and VSS. The internal potential VPP can be used in the row decoder 140, the internal potentials VOD and VARY can be used in the sense amplifiers included in the memory array 150, and the internal potential VPERI can be used in many other circuit blocks.

The power supply terminals may also be supplied with power supply potential VDDQ. The power supply potential VDDQ can be supplied to the input/output circuit 160 together with the power supply potential VSS. The power supply potential VDDQ can be the same potential as the power supply potential VDD in some embodiments of the present technology. The power supply potential VDDQ can be a different potential from the power supply potential VDD in other embodiments of the present technology. The dedicated power supply potential VDDQ can be used for the input/output circuit 160 so that power supply noise generated by the input/output circuit 160 does not propagate to the other circuit blocks.

The clock terminals and data clock terminals may be supplied with external clock signals and complementary external clock signals. The external clock signals CK, CKF, WCK, WCKF can be supplied to a clock input circuit 133. The CK and CKF signals can be complementary, and the WCK and WCKF signals can also be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 133 can receive the external clock signals. For example, when enabled by a CKE signal from the command decoder 115, an input buffer can receive the CK and CKF signals and the WCK and WCKF signals. The clock input circuit 133 can receive the external clock signals to generate internal clock signals ICLK. The internal clock signals ICLK can be supplied to an internal clock circuit 130. The internal clock circuit 130 can provide various phase and frequency controlled internal clock signals based on the received internal clock signals ICLK and a clock enable signal CKE from the command decoder 115.

For example, the internal clock circuit 130 can include a clock path (not shown in FIG. 1B) that receives the internal clock signal ICLK and provides various clock signals to the command decoder 115. The internal clock circuit 130 can further provide input/output (I/O) clock signals. The I/O clock signals can be supplied to an input/output circuit 160 and can be used as a timing signal for determining an output timing of read data and the input timing of write data. The I/O clock signals can be provided at multiple clock frequencies so that data can be output from and input to the memory device 100 at different data rates. A higher clock frequency may be desirable when high memory speed is desired. A lower clock frequency may be desirable when lower power consumption is desired. The internal clock signals ICLK can also be supplied to a timing generator 135 and thus various internal clock signals can be generated.

The command terminals and address terminals may be supplied with an address signal and a bank address signal from outside the memory device 100. The address signal and the bank address signal supplied to the address terminals can be transferred, via input buffers 106 of a command/address input circuit 105, to an address decoder 110. The address decoder 110 can receive the address signals and supply a decoded row address signal (XADD) to the row decoder 140 (which may be referred to as a row driver), and a decoded column address signal (YADD) to the column decoder 145 (which may be referred to as a column driver). The address decoder 110 can also receive the bank address portion of the ADDR input and supply the decoded bank address signal (BADD) and supply the bank address signal to both the row decoder 140 and the column decoder 145.

The command and address terminals may be supplied with command signals CMD, address signals ADDR, and chip select signals CS, from a memory controller. The command signals may represent various memory commands from the memory controller (e.g., refresh commands, activate commands, precharge commands, access commands, which can include read commands and write commands). The select signal CS may be used to select the memory device 100 to respond to commands and addresses provided to the command and address terminals. When an active CS signal is provided to the memory device 100, the commands and addresses can be decoded and memory operations can be performed. The command signals CMD may be provided as internal command signals ICMD to a command decoder 115 via the command/address input circuit 105.

The command decoder 115 may include circuits to decode the internal command signals ICMD to generate various internal signals and commands for performing memory operations, for example, a row command signal to select a word line and a column command signal to select a bit line. Other examples of memory operations that the memory device 100 may perform based on decoding the internal command signals ICMD includes a refresh command (e.g., re-establishing full charges stored in individual memory cells of the memory array 150), an activate command (e.g., activating a row in a particular bank, in some cases for subsequent access operations), or a precharge command (e.g., deactivating the activated row in the particular bank). The internal command signals can also include output and input activation commands, such as clocked command CMDCK (not shown in FIG. 1B).

The command decoder 115, in some embodiments, may further include one or more registers 128 for tracking various counts and/or values (e.g., counts of refresh commands received by the memory device 100 or self-refresh operations performed by the memory device 100) and/or for storing various operating conditions for the memory device 100 to perform certain functions, features, and modes (or test modes). As such, in some embodiments, the registers 128 (or a subset of the registers 128) may be referred to as mode registers. Additionally, or alternatively, the memory device 100 may include registers 128 as a separate component outside of the command decoder 115. In some embodiments, the registers 128 may include multi-purpose registers (MPRs) configured to write and/or read specialized data to and/or from the memory device 100.

When a read command is issued to a bank with an open row and a column address is timely supplied as part of the read command, read data can be read from memory cells in the memory array 150 designated by the row address (which may have been provided as part of the activate command identifying the open row) and column address. The read command may be received by the command decoder 115, which can provide internal commands to an input/output circuit 160 so that read data can be output from the data terminals DQ, RDQS, DBI, and DMI via read/write amplifiers 155 and the input/output circuit 160 according to the RDQS clock signals. The read data may be provided at a time defined by read latency information RL that can be programmed in the memory device 100, for example, in a mode register (e.g., one or more of the registers 128). The read latency information RL can be defined in terms of clock cycles of the CK clock signal. For example, the read latency information RL can be a number of clock cycles of the CK signal after the read command is received by the memory device 100 when the associated read data is provided.

When a write command is issued to a bank with an open row and a column address is timely supplied as part of the write command, write data can be supplied to the data terminals DQ, DBI, and DMI according to the WCK and WCKF clock signals. The write command may be received by the command decoder 115, which can provide internal commands to the input/output circuit 160 so that the write data can be received by data receivers in the input/output circuit 160, and supplied via the input/output circuit 160 and the read/write amplifiers 155 to the memory array 150. The write data may be written in the memory cell designated by the row address and the column address. The write data may be provided to the data terminals at a time that is defined by write latency WL information. The write latency WL information can be programmed in the memory device 100, for example, in a mode register (e.g., one or more of the registers 128). The write latency WL information can be defined in terms of clock cycles of the CK clock signal. For example, the write latency information WL can be a number of clock cycles of the CK signal after the write command is received by the memory device 100 when the associated write data is received.

As discussed above, the command/address input circuit 105 of the memory device 100 can include input buffers 106. The input buffers 106 can be configured to receive and temporarily store signals received at external terminals of the memory device 100. For example, the input buffers 106 can be configured to receive and temporarily store address signals ADDR, chip select signals CS, mirror enable signals MIR (also referred to herein as “mirror enable control signals”), and/or connectivity testmode enable control signals TEN (also referred to herein as “connectivity test enable signals,” “connectivity testmode enable signals,” “connectivity test enable control signals,” and the like), among other signals.

Additionally, or alternatively, the input buffers 106 can be configured to receive and temporarily store command signals CMD. In some embodiments, the command signals CMD can be received as a plurality of command-address signals. As a specific example, in embodiments in which the memory device 100 is or includes one or more DDR5 DRAM devices, the command signals CMD can include fourteen different command-address signals CA0-CA13. Continuing with this example, the input buffers 106 can include fourteen corresponding command-address input buffers.

As discussed above, not every command-address signal (e.g., not every command-address signal CA0-CA13 in the above example) must be used with every command signal. Accordingly, the memory device 100 can include input buffer control circuitry 107 to selectively disable (or enable) one or more command-address input buffers 106 of the command/address input circuit 105 while the corresponding command-address signal(s) is/are not being used. As a specific example, as discussed in greater detail below, the input buffer control circuitry 107 can be configured to selectively disable command-address input buffers 106 corresponding to command-address signal CA12 and/or to command-address signal CA13 when cither or both of these signals are not used with command signals transmitted to and/or received by the memory device 100.

In some embodiments, the input buffer control circuitry 107 can determine that one or more command-address signals will not be used with command signals (and can selectively disable one or more corresponding command-address input buffers 106) based at least in part on implementation of the memory device 100. For example, the input buffer control circuitry 107 can determine that one or more command-address signals will not be used with command signals (and can selectively disable one or more corresponding command-address input buffers 106) based at least in part on whether the memory device 100 is implemented in a 3DS (e.g., a two-high, four-high, or other 3DS). As another example, the input buffer control circuitry 107 can determine that one or more command-address signals will not be used with command signals (and can selectively disable one or more corresponding command-address input buffers 106) based at least in part on memory density of the memory array 150, which can specify a maximum number of utilized address bits and/or command-address signals.

In these and other embodiments, the input buffer control circuitry 107 can determine that one or more command-address signals will not be used with command signals (and can selectively disable one or more corresponding command-address input buffers 106) based at least in part on an operating mode of the memory device 100. For example, the input buffer control circuitry 107 can determine that one or more command-address signals will not be used with command signals (and can selectively disable one or more corresponding command-address input buffers 106) based at least in part on whether the memory device 100 is in an active mode of operation and/or whether the memory device 100 is in an idle mode of operation. As another example, the input buffer control circuitry 107 can determine that one or more command-address signals will not be used with command signals (and can selectively disable one or more corresponding command-address input buffers 106) based at least in part on whether a mirror function of the memory device is enabled (e.g., based on the mirror enable signal MIR) and/or on whether a test function of the memory device is enabled (e.g., based on the connectivity test enable signal TEN).

In some embodiments, when the input buffer control circuitry 107 selectively disables a command-address input buffer 106, current consumption of the command-address input buffer 106 can be reduced, minimized, or zero. This can be especially advantageous in high-frequency applications of the memory device 100 in which current consumption of enabled command-address input buffers 106 can increase. Thus, by selectively disabling command-address input buffers 106 when corresponding command-address signals are not being utilized, current/power consumption of the memory device 100 can be reduced.

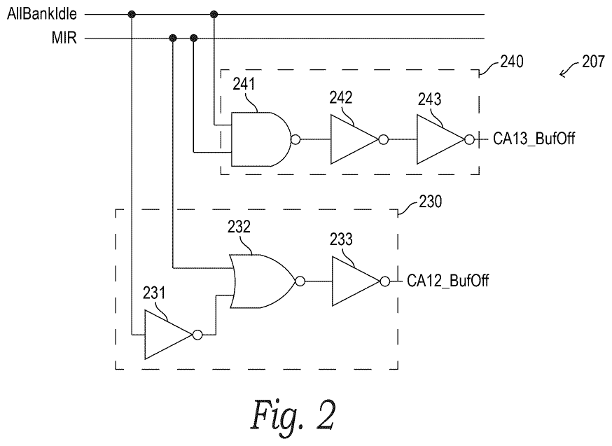

Various examples of input buffer control circuitry configured in accordance with embodiments of the present technology are described in detail below with reference to FIGS. 2-7. For the sake of example and clarity, these examples of input buffer control circuitry are described in detail below as control circuitry for (i) a first command-address input buffer that corresponds to command-address signal CA12 of a DDR5 DRAM device and (ii) a second command-address input buffer that corresponds to command-address signal CA13 of the DDR5 DRAM device. It will be appreciated that aspects of the present technology are equally applicable to control circuitry for other input buffers of a DDR5 DRAM or other memory device. Such other applications are within the scope of the present technology.

FIG. 2 is a partially schematic circuit diagram of input buffer control circuitry 207 configured in accordance with various embodiments of the present technology. The input buffer control circuitry 207 can be an example of the input buffer control circuitry 107 of FIG. 1B or other input buffer control circuitry configured in accordance with various embodiments of the present technology. As shown, the input buffer control circuitry 207 includes first control circuitry 230 for a first command-address input buffer and second control circuitry 240 for a second command-address input buffer. In some embodiments, the first command-address input buffer (i) can be an example of one of the command-address input buffers 106 of FIG. 1B or other input buffers of the present technology and/or (ii) can correspond to command-address signal CA12 or another signal received by a memory device (e.g., one of the memory devices 100a-100h of FIG. 1A and/or the memory device 100 of FIG. 1B). In these and other embodiments, the second command-address input buffer (i) can be an example of one of the command-address input buffers 106 of FIG. 1B or other input buffers of the present technology and/or (ii) can correspond to command-address signal CA13 or another signal received by a memory device (e.g., one of the memory devices 100a-100h of FIG. 1A and/or the memory device 100 of FIG. 1B).

Referring to the first control circuitry 230, the first control circuitry 230 includes a first inverter 231, a NOR logic gate 232, and a second inverter 233. The first inverter 231 includes (i) an input configured to receive an all bank idle signal AllBankIdle, and (ii) an output coupled to a first input of the NOR logic gate 232. The NOR logic gate 232 further includes (i) a second input configured to receive a mirror enable signal MIR, and (ii) an output coupled to an input of the second inverter 233. The second inverter 233 is configured to output an input buffer control signal CA12_BufOff. The output of the second inverter 233 can correspond to an output of the first control circuitry 230.

In some embodiments, the all bank idle signal AllBankIdle can correspond to an idle mode of operation of the memory device. For example, the all bank idle signal AllBankIdle can be high when the memory device is in an idle mode of operation and can be low when the memory device is outside of the idle mode of operation (e.g., when the memory device is in an active mode of operation). In these and other embodiments, functionality of input buffers of the memory device can be swapped when the mirror function of the memory device is enabled. For example, in DDR5 DRAM devices, functionality of an input buffer corresponding to command-address signal CA12 can be swapped with functionality of an input buffer corresponding to command-address signal CA13 when the mirror function is enabled. In the illustrated embodiment, when the mirror function is enabled, functionality of the first input buffer corresponding to the first control circuitry 230 can be swapped with functionality of the second input buffer corresponding to the second control circuitry 240.

In operation, when the all bank idle signal AllBankIdle is high (corresponding to when the memory device is in the idle mode of operation) and the mirror enable signal MIR is low (corresponding to when the mirror function of the memory device is disabled), the first control circuitry 230 can output the input buffer control signal CA12_BufOff in a low state. When the input buffer control signal CA12_BufOff is low, the first input buffer corresponding to the first control circuitry 230 can be enabled to receive and temporarily hold command-address signal CA12. Stated another way, the first input buffer can be enabled when the memory device is in the idle mode of operation and the mirror function is disabled.

For all other combinations of the all bank idle signal AllBankIdle and the mirror enable signal MIR (e.g., when the all bank idle signal AllBankIdle signal is low and/or when the mirror enable signal MIR is high), the first control circuitry 230 can output the input buffer control signal CA12_BufOff in a high state. When the input buffer control signal CA12_BufOff is high, the first input buffer corresponding to the first control circuitry 230 can be disabled to receive and temporarily hold command-address signal CA12. Stated another way, the first input buffer can be disabled when the memory device is outside of the idle mode of operation (e.g., is in an active mode of operation) and/or when the mirror function is enabled (e.g., corresponding to when the functionality of the first input buffer is swapped with the functionality of the second input buffer).

Referring now to the second control circuitry 240, the second control circuitry 240 includes a NAND logic gate 241, a first inverter 242, and a second inverter 243. The NAND logic gate 241 includes (i) a first input configured to receive the all bank idle signal AllBankIdle, (ii) a second input configured to receive the mirror enable signal MIR, and (iii) an output coupled to an input of the first inverter 242. The first inverter 242 includes an output coupled to an input of the second inverter 243, and the second inverter 243 is configured to output an input buffer control signal CA13_BufOff. The output of the second inverter 243 can correspond to an output of the second control circuitry 240.

In operation, when the all bank idle signal AllBankIdle is high (corresponding to when the memory device is in the idle mode of operation) and the mirror enable signal MIR is high (corresponding to when the mirror function is enabled), the second control circuitry 240 can output the input buffer control signal CA13_BufOff in a low state. When the input buffer control signal CA13_BufOff is low, the second input buffer corresponding to the second control circuitry 240 can be enabled to receive and temporarily hold command-address signal CA13. Stated another way, the second input buffer can be enabled when the memory device is in the idle mode of operation and the mirror function is enabled.

For all other combinations of the all bank idle signal AllBankIdle and the mirror enable signal MIR (e.g., when the all bank idle signal AllBankIdle signal is low and/or when the mirror enable signal MIR is low), the second control circuitry 240 can output the input buffer control signal CA13_BufOff in a high state. When the input buffer control signal CA13_BufOff is high, the second input buffer corresponding to the second control circuitry 240 can be disabled to receive and temporarily hold command-address signal CA13. Stated another way, the second input buffer can be disabled when the memory device is outside of the idle mode of operation (e.g., in in an active mode of operation) and/or when the mirror function is disabled (e.g., corresponding to when the functionality of the first input buffer is not swapped with the functionality of the second input buffer).

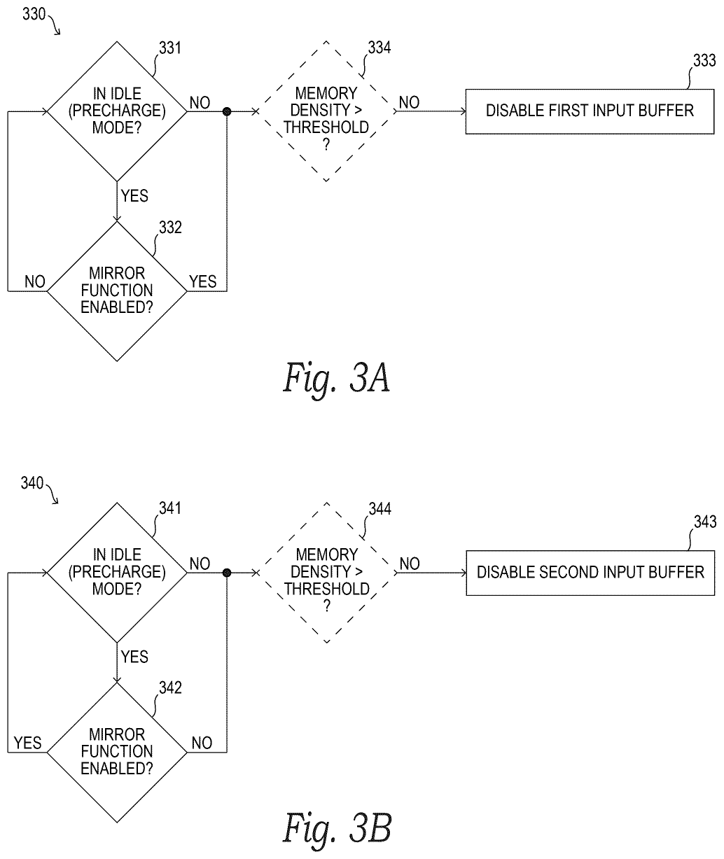

FIGS. 3A and 3B are flow diagrams illustrating methods 330 and 340, respectively, of controlling one or more input buffers of a memory device in accordance with various embodiments of the present technology. In some embodiments, the method 330 of FIG. 3A can correspond to the first control circuitry 230 of FIG. 2 or other control circuitry of the present technology. In these and other embodiments, the method 340 of FIG. 3B can correspond to the second control circuitry 240 of FIG. 2 or other control circuitry of the present technology.

Referring to the method 330 of FIG. 3A, the method 330 begins at block 331 by determining whether the memory device is in an idle mode of operation. In some embodiments, determining whether the memory device is in the idle mode of operation can include monitoring an all bank idle signal AllBankIdle. For example, when the all bank idle signal AllBankIdle is high, the method 330 can determine that the memory device is in the idle mode of operation. And when the all bank idle signal AllBankIdle is low, the method 330 can determine that the memory device is not in (or is outside of) the idle mode of operation. Continuing with this example, determining whether the memory device is in the idle mode of operation can include determining whether the all bank idle signal AllBankIdle is high or low. If the method 330 determines that the memory device is not in the idle mode of operation (block 331: No), the method 330 can proceed to block 333 to turn off the first input buffer. On the other hand, if the method 330 determines that the memory device is in the idle mode of operation (block 331: Yes), the method 330 can proceed to block 332.

At block 332, the method 330 continues by determining whether a mirror function of the memory device is enabled. In some embodiments, determining whether the mirror function of the memory device is enabled can include monitoring a mirror enable signal MIR. For example, when the mirror enable signal MIR is high, the method 330 can determine that the mirror function is enabled. And when the mirror enable signal MIR is low, the method 330 can determine that the mirror function is disabled. Continuing with this example, determining whether the mirror function of the memory device is enabled can include determining whether the mirror signal is high or low. If the method 330 determines that the mirror function of the memory device is enabled (block 332: Yes), the method 330 can proceed to block 333 to turn off the first input buffer. On the other hand, if the method 330 determines that the mirror function of the memory device is not enabled or is disabled (block 332: No), the first input buffer can be (or remain) enabled and the method 330 can return to block 331.

At block 333, the method 330 continues by disabling the first input buffer. As discussed above, the first input buffer can be an input buffer of the memory device configured to receive and temporarily store a command-address signal (e.g., command-address signal CA12) of command signals received by the memory device. In these embodiments, disabling the first input buffer can include disabling the first input buffer when the corresponding command-address signal is not utilized. In these and other embodiments, disabling the first input buffer can include disabling the first input buffer such that current or power consumption of the first input buffer is reduced, minimized, or zero.

Although the blocks 331-333 of the method 330 are discussed and illustrated in a particular order, the method 330 illustrated in FIG. 3A is not so limited. In other embodiments, the method 330 can be performed in a different order. In these and other embodiments, any of the blocks 331-333 of the method 330 can be performed before, during, and/or after any of the other blocks 331-333 of the method 330. Moreover, a person of ordinary skill in the relevant art will recognize that the illustrated method 330 can be altered and still remain within these and other embodiments of the present technology. For example, one or more blocks 331-333 of the method 330 illustrated in FIG. 3A can be omitted and/or repeated in some embodiments. As another example, the method 330 can include one or more additional blocks. As a specific example, the first input buffer can be selectively disabled based at least in part on a memory density of a corresponding memory device. For example, for a memory device having a 16 Gbit density, sixteen address bits (e.g., R0-R15) can be used to provide every requisite row address. Thus, continuing with this example, input buffer control circuitry can be used to selectively disable input buffers (e.g., the first input buffer) whenever these input buffers would be used to provide row addresses (e.g., R16) that are only used for memory densities greater than 16 Gbit. In such embodiments, as shown in FIG. 3A, the method 330 can additional include optional block 334. Continuing with this specific example, if the method 330 determines that the memory device is not in the idle mode of operation (block 331: No), the method 330 can proceed to block 334 to determine whether a memory density of the memory device is greater than a threshold (e.g., 16 Gbit). In the event that the method 330 determines that the memory density of the corresponding memory device is not greater than the threshold (block 334: No), the method 330 can proceed to block 333 to disable the first input buffer. On the other hand, in the event that the method 330 determines that the memory density of the corresponding memory device is greater than the threshold (block 334: Yes), the method 330 can take no action, return to block 331, and/or enable the first input buffer/leave it enabled. In some embodiments, the method 330 can be performed in a different order. For example, block 334 can be performed before block 331 such that the method 330 can proceed from block 331 to block 333 to disable the second input buffer having already determined that the memory density of the corresponding memory device is less than (or equal to) the threshold.

The method 330 is primarily illustrated in FIG. 3A and described above as a method to selectively disable the first input buffer. Stated another way, the first input buffer can be enabled (e.g., by default), and the method 330 can be used to determine when to selectively disable the first input buffer. In other embodiments, the first input buffer can be disabled (e.g., by default), and the method 330 can be used to determine when to selectively enable the first input buffer. In these embodiments, block 333 can be omitted, and the method 330 can include another block to selectively enable (or turn on) the first input buffer (e.g., when the memory device enters the idle mode of operation and the mirror function is not enabled).

Referring now to the method 340 of FIG. 3B, the method 340 begins at block 341 by determining whether the memory device is in an idle mode of operation. In some embodiments, determining whether the memory device is in the idle mode of operation can include monitoring an all bank idle signal AllBankIdle. For example, when the all bank idle signal AllBankIdle is high, the method 340 can determine that the memory device is in the idle mode of operation. And when the all bank idle signal AllBankIdle is low, the method 340 can determine that the memory device is not in (or is outside of) the idle mode of operation. Continuing with this example, determining whether the memory device is in the idle mode of operation can include determining whether the all bank idle signal AllBankIdle is high or low. If the method 340 determines that the memory device is not in the idle mode of operation (block 341: No), the method 340 can proceed to block 343 to turn off the second input buffer. On the other hand, if the method 340 determines that the memory device is in the idle mode of operation (block 341: Yes), the method 340 can proceed to block 342.

At block 342, the method 340 continues by determining whether a mirror function of the memory device is enabled. In some embodiments, determining whether the mirror function of the memory device is enabled can include monitoring a mirror enable signal MIR. For example, when the mirror enable signal MIR is high, the method 340 can determine that the mirror function is enabled. And when the mirror enable signal MIR is low, the method 340 can determine that the mirror function is disabled. Continuing with this example, determining whether the mirror function of the memory device is enabled can include determining whether the mirror signal is high or low. If the method 340 determines that the mirror function of the memory device is enabled (block 342: Yes), the second input buffer can be (or remain) enabled and the method 340 can return to block 341. On the other hand, if the method 340 determines that the mirror function of the memory device is not enabled or is disabled (block 342: No), the method 340 can proceed to block 343 to turn off the second input buffer.

At block 343, the method 340 continues by disabling the second input buffer. As discussed above, the second input buffer can be an input buffer of the memory device configured to receive and temporarily store a command-address signal (e.g., command-address signal CA13) of command signals received by the memory device. In these embodiments, disabling the second input buffer can include disabling the second input buffer when the corresponding command-address signal is not utilized. In these and other embodiments, disabling the second input buffer can include disabling the second input buffer such that current or power consumption of the second input buffer is reduced, minimized, or zero.

Although the blocks 341-343 of the method 340 are discussed and illustrated in a particular order, the method 340 illustrated in FIG. 3B is not so limited. In other embodiments, the method 340 can be performed in a different order. In these and other embodiments, any of the blocks 341-343 of the method 340 can be performed before, during, and/or after any of the other blocks 341-343 of the method 340. As a specific example, block 342 can be performed before or while performing block 341. Moreover, a person of ordinary skill in the relevant art will recognize that the illustrated method 340 can be altered and still remain within these and other embodiments of the present technology. For example, one or more blocks 341-343 of the method 340 illustrated in FIG. 3B can be omitted and/or repeated in some embodiments. As another example, the method 340 can include one or more additional blocks. As a specific example, the second input buffer can be selectively disabled based at least in part on a memory density of a corresponding memory device. For example, for a memory device having a 16 Gbit density, sixteen address bits (e.g., R0-R15) can be used to provide every requisite row address. Thus, continuing with this example, input buffer control circuitry can be used to selectively disable input buffers (e.g., the second input buffer) whenever these input buffers would be used to provide row addresses (e.g., R17) that are only used for memory densities greater than 16 Gbit. In such embodiments, as shown in FIG. 3B, the method 340 can additionally include optional block 344. Continuing with this specific example, if the method 340 determines that the memory device is not in the idle mode of operation (block 341: No), the method 340 can proceed to block 344 to determine whether a memory density of the memory device is greater than a threshold (e.g., 16 Gbit). In the event that the method 340 determines that the memory density of the corresponding memory device is not greater than the threshold (block 344: No), the method 340 can proceed to block 343 to disable the second input buffer. On the other hand, in the event that the method 340 determines that the memory density of the corresponding memory device is greater than the threshold (block 344: Yes), the method 340 can take no action, return to block 341, and/or enable the second input buffer/leave it enabled. In some embodiments, the method 340 can be performed in a different order. For example, block 344 can be performed before block 341 such that the method 340 can proceed from block 341 to block 343 to disable the second input buffer having already determined that the memory density of the corresponding memory device is less than (or equal to) the threshold.

The method 340 is primarily illustrated in FIG. B and described above as a method to selectively disable the second input buffer. Stated another way, the second input buffer can be enabled (e.g., by default), and the method 340 can be used to determine when to selectively disable the second input buffer. In other embodiments, the second input buffer can be disabled (e.g., by default), and the method 340 can be used to determine when to selectively enable the second input buffer. In these embodiments, block 343 can be omitted, and the method 340 can include another block to selectively enable (or turn on) the first input buffer (e.g., when the memory device enters the idle mode of operation and the mirror function is enabled).

In some embodiments, the method 330 of FIG. 3A can be combined with the method 340 of FIG. 3B. For example, block 331 (FIG. 3A) can be combined with block 341 (FIG. 3B), block 332 (FIG. 3A) can be combined with block 342 (FIG. 3B), and/or block 333 (FIG. 3A) can be combined with block 343 (FIG. 3B). In the combined method, the method can disable both the first input buffer and the second input buffer when the memory device is not in the idle mode of operation. Additionally, or alternatively, the combined method (i) can disable the first input buffer when the memory device is in the idle mode of operation and the mirror function is enabled, and (ii) can disable the second input buffer when the memory device is in the idle mode of operation and the mirror function is not enabled (or is disabled).

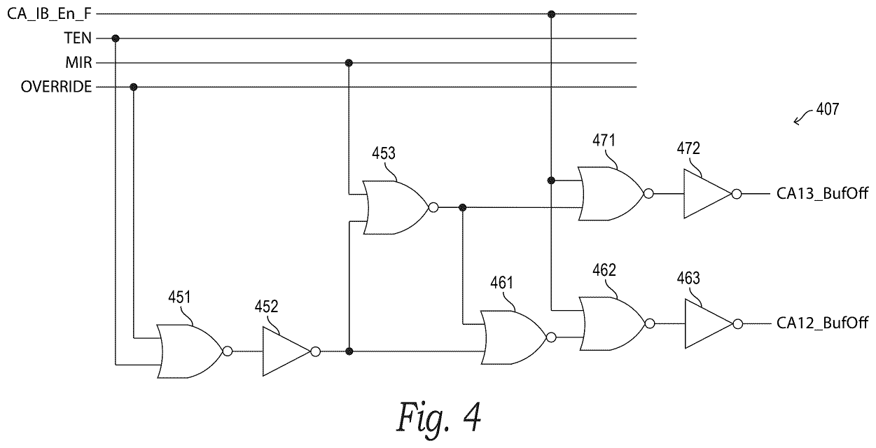

FIG. 4 is a partially schematic circuit diagram of input buffer control circuitry 407 configured in accordance with various embodiments of the present technology. The input buffer control circuitry 407 can be an example of the input buffer control circuitry 107 of FIG. 1B or other input buffer control circuitry configured in accordance with various embodiments of the present technology. The input buffer control circuitry 407 can include (i) first components (or logic gates) for controlling a first command-address input buffer and (ii) second component (or logic gates) for controlling a second command-address input buffer. In some embodiments, the first command-address input buffer (i) can be an example of one of the command-address input buffers 106 of FIG. 1B or other input buffers of the present technology and/or (ii) can correspond to command-address signal CA12 or another signal received by a memory device (e.g., one of the memory devices 100a-100h of FIG. 1A and/or the memory device 100 of FIG. 1B). In these and other embodiments, the second command-address input buffer (i) can be an example of one of the command-address input buffers 106 of FIG. 1B or other input buffers of the present technology and/or (ii) can correspond to command-address signal CA13 or another signal received by a memory device (e.g., one of the memory devices 100a-100h of FIG. 1A and/or the memory device 100 of FIG. 1B).

Describing the input buffer control circuitry 407 from left to right as shown in FIG. 4, the input buffer control circuitry 407 includes a first NOR logic gate 451, a first inverter 452, and a second NOR logic gate 453. The first NOR logic gate 451 includes (i) a first input configured to receive an override signal OVERRIDE, (ii) a second input configured to receive a connectivity test/testmode enable control signal TEN (also referred to herein as a “connectivity test enable signal” and as a “connectivity test enable control signal”), and (iii) an output coupled to an input of the first inverter 452. The first inverter 452 further includes an output coupled to a first input of the second NOR logic gate 453, and the second NOR logic gate 453 further includes a second input configured to receive a mirror enable signal MIR.

The input buffer control circuitry 407 further includes a third NOR logic gate 461, a fourth NOR logic gate 462, a second inverter 463, a fifth NOR logic gate 471, and a third inverter 472. An output of the second NOR logic gate 453 is coupled to a first input of the third NOR logic gate 461 and to a first input of the fifth NOR logic gate 471. The third NOR logic gate 461 includes (i) a second input configured to receive the output of the first inverter 452, and (ii) an output coupled to a first input of the fourth NOR logic gate 462. The fourth NOR logic gate 462 and the fifth NOR logic gate 471 each includes a second input configured to receive a command-address input buffer enable signal CA_IB_En_F. An output of the fourth NOR logic gate 462 is coupled to an input of the second inverter 463, and an output of the fifth NOR logic gate 471 is coupled to an input of the third inverter 472. The second inverter 463 is configured to output an input buffer control signal CA12_BufOff, and the third inverter 472 is configured to output an input buffer control signal CA13_BufOff. The output of the second inverter 463 can correspond to a first output of the input buffer control circuitry 407, and the output of the third inverter 472 can correspond to a second output of in the input buffer control circuitry 407.

The command-address input buffer enable signal CA_IB_En_F can be used to selectively disable the first and second input buffers. More specifically, when the command-address input buffer enable signal CA_IB_En_F signal is high (or de-asserted), the first output CA12_BufOff and the second output CA13_BufOff of the input buffer control circuitry 407 are high (e.g., regardless of the states of the other signals). When the first output CA12_BufOff and the second output CA13_BufOff of the input buffer control circuitry 407 are high, the first input buffer and the second input buffer, respectively, are disabled or turned off. In some embodiments, the command-address input buffer enable signal CA_IB_En_F can be de-asserted when the memory device enters an active mode of operation and/or another mode of operation that is outside an idle mode of operation. In these and other embodiments, the command-address input buffer enable signal CA_IB_EN_F can be asserted when the memory device enters the idle mode of operation and/or when all banks of the memory device are idle.

The override signal OVERRIDE can be used to “force” the first output CA12_BufOff and the second output CA13_BufOff low (e.g., to override components of the input buffer control circuitry 407 configured to receive the connectivity test enable TEN signal and/or the mirror enable signal MIR). More specifically, when the override signal OVERRIDE is high or asserted (and the command-address input buffer enable signal CA_IB_EN_F signal is low), the first output CA12_BufOff and the second output CA13_BufOff of the input buffer control circuitry 407 are low (e.g., regardless of the state of the mirror enable signal MIR). When the first output CA12_BufOff and the second output CA13_BufOff of the input buffer control circuitry 407 are low, the first input buffer and the second input buffer, respectively are enabled or turned on.

Operation of the input buffer control circuitry 407 when the command-address input buffer enable signal CA_IB_En_F is low (or asserted) and the override signal OVERRIDE is low (or de-asserted) will now be described. Referring first to the connectivity test enable signal TEN, when the connectivity test enable signal TEN is high (or asserted), the first output CA12_BufOff and the second output CA13_BufOff are low (e.g., regardless of the state of the mirror enable signal MIR), meaning the first input buffer and the second input buffer are enabled or turned on. On the other hand, when the connectivity test enable signal TEN is low (or de-asserted), the states of the first output CA12_BufOff and the second output CA13_BufOff can depend on the state of the mirror enable signal MIR. More specifically, when the mirror enable signal MIR is low (or de-asserted), the first output CA12_BufOff is low (meaning the first input buffer is enabled or turned on) and the second output CA13_BufOff is high (meaning that the second input buffer is disabled or turned off). On the other hand, when the mirror enable signal MIR is high (or asserted), the first output CA12_BufOff is high (meaning the first input buffer is disabled or turned off) and the second output CA13_BufOff is low (meaning that the second input buffer is enabled or turned on).

In some embodiments, the override signal OVERRIDE can be omitted (or not used). For example, the input buffer control circuitry 407 can omit the first NOR logic gate 451 and the first inverter 452, and the connectivity test enable signal TEN can be fed (e.g., directly) into (i) the first input of the second NOR logic gate 453 and (ii) the second input of the third NOR logic gate 461. Continuing with this example, the input buffer control circuitry 407 can operate in generally the same manner (e.g., the first input buffer and the second input buffer can be enabled (or turned on) when the test connectivity enable signal TEN is high (or asserted); the first input buffer can be enabled (or turned on) and the second input buffer can be disabled (or turned off) when the test connectivity enable signal TEN and the mirror enable signal are low (or de-asserted); and the first input buffer can be disabled (or turned off) and the second input buffer can be enabled (or turned on) when the test connectivity enable signal TEN is low (or de-asserted) and the mirror enable signal MIR is high (or asserted)).

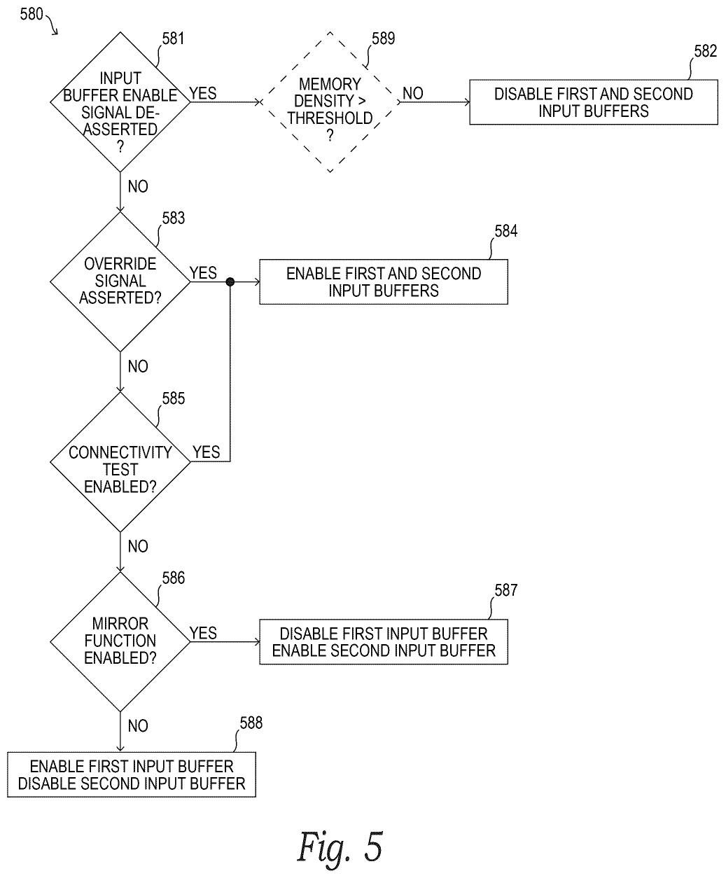

FIG. 5 is a flow diagram illustrating a method 580 of controlling one or more input buffers in accordance with various embodiments of the present technology. In some embodiments, the method 580 can correspond to the input buffer control circuitry 407 of FIG. 4 or other input buffer control circuitry of the present technology. In these and other embodiments, the one or more input buffers can include a first input buffer and a second input buffer (e.g., the input buffers 106 of FIG. 1B or other input buffers of the present technology). The method 580 is illustrated as a set of steps or blocks 581-588.

The method 580 begins at block 581 by determining whether an input buffer enable signal is de-asserted. In some embodiments, the input buffer enable signal can be the command-address input buffer enable signal CA_IB_EN_F discussed above with reference to FIG. 4. When the method 580 determines that the input buffer enable signal is de-asserted (block 581: Yes), the method 580 can proceed to block 582 to disable (or turn off) the first input buffer and the second input buffer. Disabling the first input buffer and the second input buffer can include disabling the first and second input buffers such that current/power consumed by the first and second input buffers is reduced, minimized, or zero. On the other hand, when the method 580 determines that the input buffer enable signal is not de-asserted (block 581: No), the method 580 can proceed to block 583.

At block 583, the method 580 continues by determining whether an override signal is asserted. In some embodiments, the override signal can be the override signal OVERRIDE signal discussed above with reference to FIG. 4. When the method 580 determines that the override signal is asserted (block 583: Yes), the method 580 can proceed to block 584 to enable (or turn on) the first input buffer and the second input buffer. Enabling the first input buffer and the second input buffer can include enabling the first and second input buffers such that the first and second input buffers can receive and temporarily hold corresponding signals (e.g., command-address) signals received by the memory device. On the other hand, when the method 580 determines that the override signal is not asserted (block 583: No), the method 580 can proceed to block 585.

At block 585, the method 580 continues by determining whether a connectivity test is enabled. In some embodiments, determining whether a connectivity test is enabled can include determining whether a connectivity test enable signal is asserted. The connectivity test enable signal can be the connectivity test enable signal TEN discussed above with reference to FIG. 4 or another connectivity test enable signal of the present technology. When the method 580 determines that the connectivity test is enabled (block 585: Yes), the method 580 can proceed to block 584 to enable (or turn on) the first input buffer and the second input buffer. On the other hand, when the method 580 determines that the connectivity test is not enabled (block 585: No), the method 580 can proceed to block 586.

At block 586, the method 580 can determine whether a mirror function is enabled. In some embodiments, determining whether a mirror function is enabled can include determining whether a mirror function enable signal is asserted. The mirror function enable signal can be the mirror function enable signal MIR discussed above with reference to FIG. 4 or another mirror function enable signal of the present technology. When the method 580 determines that the mirror function is enabled (block 586: Yes), the method 580 can proceed to block 587 to disable (or turn off) the first input buffer and/or enable (or turn on) the second input buffer. On the other hand, when the method 580 determines that that mirror function is not enabled (block 586: No), the method 580 can proceed to block 588 to enable (or turn on) the first input buffer and/or to disable (or turn off) the second input buffer.

Although the blocks 581-588 of the method 580 are discussed and illustrated in a particular order, the method 580 illustrated in FIG. 5 is not so limited. In other embodiments, the method 580 can be performed in a different order. In these and other embodiments, any of the blocks 581-588 of the method 580 can be performed before, during, and/or after any of the other blocks 581-588 of the method 580. As a specific example, block 583 can be performed before or while performing blocks 581. Moreover, a person of ordinary skill in the relevant art will recognize that the illustrated method 580 can be altered and still remain within these and other embodiments of the present technology. For example, one or more blocks 581-588 of the method 580 illustrated in FIG. 5 can be omitted and/or repeated in some embodiments. As a specific example, blocks 581 and 582 can be omitted in some embodiments. As another specific example, block 583 can be omitted in some embodiments. As another example, the method 580 can include one or more additional blocks. As a specific example, the first input buffer and/or the second input buffer can be selectively disabled based at least in part on a memory density of a corresponding memory device. For example, for a memory device having a 16 Gbit density, sixteen address bits (e.g., R0-R15) can be used to provide every requisite row address. Thus, continuing with this example, input buffer control circuitry can be used to selectively disable input buffers (e.g., the first input buffer and/or the second input buffer) whenever these input buffers would be used to provide row addresses (e.g., R16 and/or R17) that are only used for memory densities greater than 16 Gbit. In such embodiments, as shown in FIG. 5, the method 580 can additionally include optional block 589. Continuing with this specific example, if the method 580 determines that the input buffer enable signal is de-asserted (block 581: Yes), the method 580 can proceed to block 589 to determine whether a memory density of the memory device is greater than a threshold (e.g., 16 Gbit). In the event that the method 580 determines that the memory density of the corresponding memory device is not greater than the threshold (block 589: No), the method 580 can proceed to block 582 to disable the first input buffer and/or the second input buffer. On the other hand, in the event that the method 580 determines that the memory density of the corresponding memory device is greater than the threshold (block 589: Yes), the method 580 can take no action, return to block 581, and/or enable first input buffer and/or the second input buffer (or leave the first input buffer and/or the second input buffer enabled). In some embodiments, the method 580 can be performed in a different order. For example, block 589 can be performed before block 581 such that the method 580 can proceed from block 581 to block 582 to disable the first input buffer and/or the second input buffer having already determined that the memory density of the corresponding memory device is less than (or equal to) the threshold.

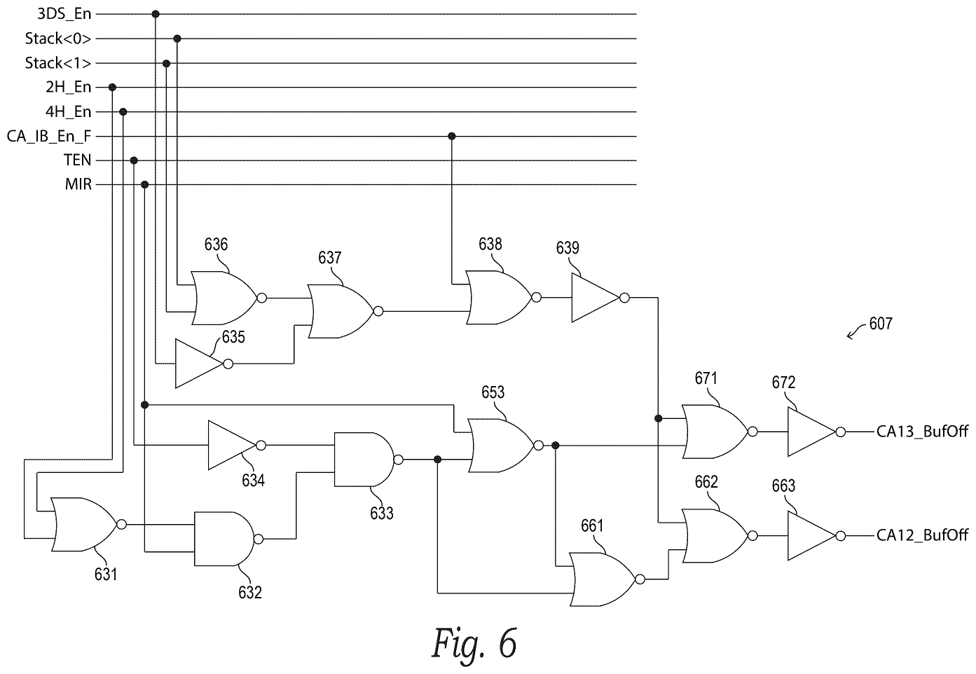

FIG. 6 is a partially schematic circuit diagram of input buffer control circuitry 607 configured in accordance with various embodiments of the present technology. The input buffer control circuitry 607 can be an example of the input buffer control circuitry 107 of FIG. 1B or other input buffer control circuitry of the present technology. The input buffer control circuitry 607 can include (i) first components (or logic gates) for controlling a first command-address input buffer and (ii) second components (or logic gates) for controlling a second command-address input buffer. In some embodiments, the first command-address input buffer (i) can be an example of one of the command-address input buffers 106 of FIG. 1B or other input buffers of the present technology and/or (ii) can correspond to command-address signal CA12 or another signal received by a memory device (e.g., one of the memory devices 100a-100h of FIG. 1A and/or the memory device 100 of FIG. 1B). In these and other embodiments, the second command-address input buffer (i) can be an example of one of the command-address input buffers 106 of FIG. 1B or other input buffers of the present technology and/or (ii) can correspond to command-address signal CA13 or another signal received by a memory device (e.g., one of the memory devices 100a-100h of FIG. 1A and/or the memory device 100 of FIG. 1B).

Describing the input buffer control circuitry 607 from left to right as shown in FIG. 6, the input buffer control circuitry 607 includes a first NOR logic gate 631, a first NAND logic gate 632, a second NAND logic gate 633, and a first inverter 634. The first NOR logic gate 631 includes (i) a first input configured to receive a two-high enable signal 2H_En, (ii) a second input configured to receive a four-high enable signal 4H_En, and (iii) an output coupled to a first input of the first NAND logic gate 632. The first NAND logic gate 632 further includes (i) a second input configured to receive a mirror enable signal MIR, and (ii) an output coupled to a first input of the second NAND logic gate 633. An input of the first inverter 634 is configured to receive a connectivity test enable signal TEN, and an output of the first inverter 634 is coupled to a second input of the second NAND logic gate 633.

The input buffer control circuitry 607 further includes a second NOR logic gate 653, a third NOR logic gate 661, a fourth NOR logic gate 662, a second inverter 663, a fifth NOR logic gate 671, and a third inverter 672. An output of the second NAND logic gate 633 is coupled to (i) a first input of the second NOR logic gate 653 and (ii) a first input of the third NOR logic gate 661. A second input of the second NOR logic gate 653 is configured to receive the mirror enable signal MIR, and an output of the second NOR logic gate 653 is coupled (i) a first input of the fifth NOR logic gate 671 and (ii) to a second input of the third NOR logic gate 661. An output of the third NOR logic gate 661 is coupled to a first input of the fourth NOR logic gate 662.

As shown, the input buffer control circuitry 607 further includes a fourth inverter 635, a sixth NOR logic gate 636, a seventh NOR logic gate 637, an eighth NOR logic gate 638, and a fifth inverter 639. An input of the fourth inverter 635 is configured to receive a 3DS enable signal 3DS_En, and an output of the fourth inverter 635 is coupled to a first input of the seventh NOR logic gate 637. The sixth NOR logic gate sixth NOR logic gate 636 includes (i) a first input configured to receive a first slice address signal Stack<0>, (ii) a second input configured to receive a second slice address signal Stack<1>, and (iii) an output coupled to a second input of the seventh NOR logic gate 637. The eighth NOR logic gate 638 includes (i) a first input configured to receive a command-address input buffer enable signal CA_IB_En_F, (ii) a second input coupled to an output of the seventh NOR logic gate 637, and (iii) an output coupled to an input of the fifth inverter 639.

The fourth NOR logic gate 662 and the fifth NOR logic gate 671 each includes a second input configured to receive an output of the fifth inverter 639. An output of the fourth NOR logic gate 662 is coupled to an input of the second inverter 663, and an output of the fifth NOR logic gate 671 is coupled to an input of the third inverter 672. The second inverter 663 is configured to output an input buffer control signal CA12_BufOff, and the third inverter 672 is configured to output an input buffer control signal CA13_BufOff. The output of the second inverter 663 can correspond to a first output of the input buffer control circuitry 607, and the output of the third inverter 672 can correspond to a second output of in the input buffer control circuitry 607.

As discussed above, the command-address input buffer enable signal CA_IB_En_F can be used to selectively disable the first and second input buffers. More specifically, when the command-address input buffer enable signal CA_IB_En_F signal is high (or de-asserted), the first output CA12_BufOff and the second output CA13_BufOff of the input buffer control circuitry 407 are high (e.g., regardless of the states of the other signals). When the first output CA12_BufOff and the second output CA13_BufOff of the input buffer control circuitry 407 are high, the first input buffer and the second input buffer, respectively, are disabled or turned off. In some embodiments, the command-address input buffer enable signal CA_IB_En_F can be de-asserted when the memory device enters an active mode of operation. In these and other embodiments, the command-address input buffer enable signal CA_IB_EN_F can be asserted when the memory device enters an idle mode of operation.

As discussed above, the connectivity test enable signal TEN can be used to indicate when a connectivity test of the memory device is enabled. Additionally, or alternatively, the mirror enable signal MIR can be used to indicate when a mirror function of the memory device is enabled.

The 3DS enable signal 3DS_En can be used to enable a 3DS mode of the memory device, or can be used to indicate when a 3DS mode of the memory device is enabled. When the 3DS mode of the memory device is enabled (e.g., when the 3DS enable signal 3DS_En is asserted or high), the two-high enable signal 2H_En and the four-high enable signal 4H_En can be used to indicate a number of possible layers of slices (two or four, respectively) in the memory device. The first slice address signal Stack<0> and the second slice address signal Stack<1> can be used to provide a slice ID to identify a slice layer from among the number of slice layers while the memory device is in a 3DS mode of operation. For example, the first slice address signal Stack<0> and the second slice address signal Stack<1> can be used to provide the following slice IDs: (1) Slice ID0 (corresponding to both the first slice address signal Stack<0> and the second slice address signal Stack<1> being de-asserted); (2) Slice ID1 (corresponding to the first slice address signal Stack<0> being asserted and the second slice address signal Stack<1> being de-asserted; (3) Slice ID2 (corresponding to the first slice address signal Stack<0> being de-asserted and the second slice address signal Stack<1> being asserted); and (4) Slice ID3 (corresponding to both the first slice address signal Stack<0> and the second slice address signal Stack<1> being asserted).

Operation of the input buffer control circuitry 607 when the command-address input buffer enable signal CA_IB_En_F is low (or asserted) will now be described. When the 3DS enable signal 3DS_En is de-asserted (or low), the input buffer control circuitry 607 operates in a manner generally similar to the input buffer control circuitry 407 described above with reference to FIG. 4. Therefore, a detailed description of operation of the input buffer control circuitry 607 while the 3DS enable signal is de-asserted is omitted here for the sake of brevity.

When the 3DS enable signal 3DS_En is asserted (or high), operation of the input buffer control circuitry 607 depends on whether the input buffer control circuitry 607 corresponds to the slice layer selected using the first slice address signal Stack<0> and the second slice address signal Stack<1>. For the sake of example, the input buffer control circuitry 607 illustrated in FIG. 6 corresponds to a first slice layer having Slice ID0 (corresponding to both the first slice address signal Stack<0> and the second slice address signal Stack<1> being de-asserted). Thus, the output CA12_BufOff and the output CA13_BufOff will be high (corresponding to the first input buffer and the second input buffer, respectively, being disabled or turned off) when the first slice address signal Stack<0> or the second slice address signal Stack<1> are asserted (or high).

On the other hand, when (a) the first slice address signal Stack<0> and the second slice address signal Stack<1> are both de-asserted (or low) and (b) the two-high enable signal 2H_En or the four-high enable signal 4H_En are asserted (or high), the input buffer control circuitry 607 operates in a manner generally similar to the input buffer control circuitry 407 described above with reference to FIG. 4. Therefore, a detailed description of operation of the input buffer control circuitry 607 while the 3DS enable signal is de-asserted is omitted here for the sake of brevity.

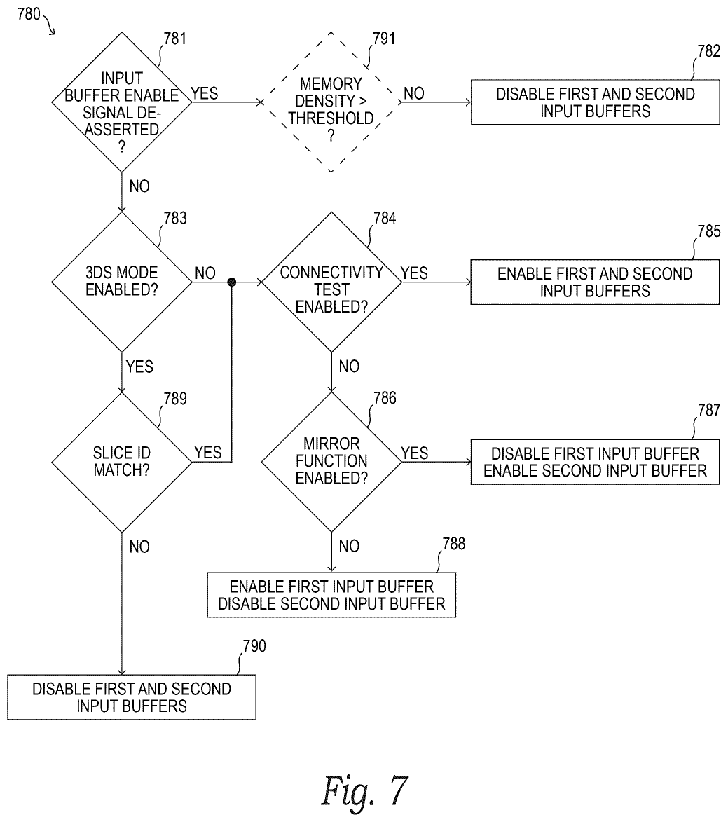

FIG. 7 is a flow diagram illustrating a method 780 of controlling one or more input buffers in accordance with various embodiments of the present technology. In some embodiments, the method 780 can correspond to the input buffer control circuitry 607 of FIG. 6 or other input buffer control circuitry of the present technology. In these and other embodiments, the one or more input buffers can include a first input buffer and a second input buffer (e.g., the input buffers 106 of FIG. 1B or other input buffers of the present technology). The method 780 is illustrated as a set of steps or blocks 781-790.

The method 780 begins at block 781 by determining whether an input buffer enable signal is de-asserted. In some embodiments, the input buffer enable signal can be the command-address input buffer enable signal CA_IB_EN_F discussed above with reference to FIG. 6. When the method 780 determines that the input buffer enable signal is de-asserted (block 781: Yes), the method 780 can proceed to block 782 to disable (or turn off) the first input buffer and the second input buffer. Disabling the first input buffer and the second input buffer can include disabling the first and second input buffers such that current/power consumed by the first and second input buffers is reduced, minimized, or zero. On the other hand, when the method 780 determines that the input buffer enable signal is not de-asserted (block 781: No), the method 780 can proceed to block 783.

At block 783, the method 780 continues by determining whether a 3DS mode of the memory device is enabled. In some embodiments, determining whether the 3DS mode of the memory device is enabled can include monitoring a status of a 3DS enable signal, such as the 3DS enable signal 3DS_En described above with reference to FIG. 6 or another suitable enable signal. When the method 780 determines that the 3DS mode of the memory device is not enabled (block 783: No), the method can proceed to block 784 to determine whether a connectivity test is enabled. Blocks 784-788 of the method 780 are generally similar to blocks 584-588 of the method 580 described above with reference to FIG. 5. Therefore, a detailed description of blocks 784-788 of the method 780 is omitted here for the sake of brevity.

On the other hand, when the method 780 determines that the 3DS mode of the memory device is enabled (block 783: Yes), the method 780 continues to block 789. At block 789, the method 780 determines whether a slice ID corresponds to the memory device. In some embodiments, a slice ID can be provided by a first slice address signal and/or a second slice address signal (e.g., the first slice address signal Stack<0> and the second slice address signal Stack<1> described above with reference to FIG. 6). In these embodiments, determining whether the slice ID corresponds to the memory device can include monitoring the first slice address signal and/or the second slice address signal. When the method 780 determines that the slide ID does not correspond to the memory device (block 789: No), the method 780 can proceed to block 790 to disable (or turn off) the first input buffer and the second input buffer. On the other hand, when the method 780 determines that the slide ID does correspond to the memory device (block 789: Yes), the method 780 can proceed to block 784, and the method 780 proceeds in a manner generally similar to blocks 584-585 of the method 580 described above with reference to FIG. 5.

Although the blocks 781-790 of the method 780 are discussed and illustrated in a particular order, the method 780 illustrated in FIG. 7 is not so limited. In other embodiments, the method 780 can be performed in a different order. In these and other embodiments, any of the blocks 781-790 of the method 780 can be performed before, during, and/or after any of the other blocks 781-790 of the method 780. As a specific example, block 783 can be performed before or while performing blocks 781. As another specific example, block 789 can be performed before or while performing block 783. Moreover, a person of ordinary skill in the relevant art will recognize that the illustrated method 780 can be altered and still remain within these and other embodiments of the present technology. For example, one or more blocks 781-790 of the method 780 illustrated in FIG. 7 can be omitted and/or repeated in some embodiments. As a specific example, blocks 781 and 782 can be omitted in some embodiments.

As another example, the method 780 can include one or more additional blocks. As a specific example, the first input buffer and/or the second input buffer can be selectively disabled based at least in part on memory density of a corresponding memory device. For example, for a memory device having a 16 Gbit density, sixteen address bits (e.g., R0-R15) can be used to provide every requisite row address. Thus, continuing with this example, input buffer control circuitry can be used to selectively disable input buffers (e.g., a first input buffer and/or a second input buffer) whenever these input buffers would be used to provide row addresses (e.g., R16 and/or R17) that are only used for memory densities greater than 16 Gbit. In such embodiments, as shown in FIG. 7, the method 780 can additionally include optional block 791. Continuing with this specific example, if the method 780 determines that the input buffer enable signal is de-asserted (block 781: Yes), the method 780 can proceed to block 791 to determine whether a memory density of the memory device is greater than a threshold (e.g., 16 Gbit). In the event that the method 780 determines that the memory density of the corresponding memory device is not greater than the threshold (block 791: No), the method 780 can proceed to block 782 to disable the first input buffer and/or the second input buffer. On the other hand, in the event that the method 780 determines that the memory density of the corresponding memory device is greater than the threshold (block 791: Yes), the method 780 can take no action, return to block 781, and/or enable first input buffer and/or the second input buffer (or leave the first input buffer and/or the second input buffer enabled). In some embodiments, the method 780 can be performed in a different order. For example, block 791 can be performed before block 781 such that the method 780 can proceed from block 781 to block 782 to disable the first input buffer and/or the second input buffer having already determined that the memory density of the corresponding memory device is less than (or equal to) the threshold.

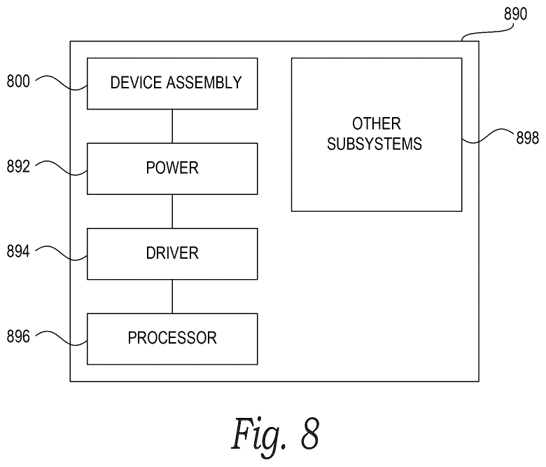

Any of the foregoing memory systems, devices, and/or methods described above with reference to FIGS. 1A-7 can be incorporated into any of a myriad of larger and/or more complex systems, a representative example of which is system 890 shown schematically in FIG. 8. The system 890 can include a semiconductor device assembly 800, a power source 892, a driver 894, a processor 896, and/or other subsystems and components 898. The semiconductor device assembly 800 can include features generally similar to those of the memory systems, devices, and/or methods described above with reference to FIGS. 1A-7. The resulting system 890 can perform any of a wide variety of functions, such as memory storage, data processing, and/or other suitable functions. Accordingly, representative systems 890 can include, without limitation, hand-held devices (e.g., mobile phones, tablets, digital readers, and digital audio players), computers, vehicles, appliances, and other products. Components of the system 890 may be housed in a single unit or distributed over multiple, interconnected units (e.g., through a communications network). The components of the system 890 can also include remote devices and any of a wide variety of computer readable media.

### CONCLUSION

As used herein, the terms “memory system” and “memory device” refer to systems and devices configured to temporarily and/or permanently store information related to various electronic devices. Accordingly, the term “memory device” can refer to a single memory die and/or to a memory package containing one or more memory dies. Similarly, the term “memory system” can refer to a system including one or more memory dies (e.g., a memory package) and/or to a system (e.g., a dual in-line memory module (DIMM)) including one or more memory packages.

Where the context permits, singular or plural terms can also include the plural or singular term, respectively. In addition, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having” and “with” are used throughout to mean including at least the recited feature(s) such that any greater number of the same feature and/or additional types of other features are not precluded. Moreover, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, it will be understood by a person of ordinary skill in the art that the signal may represent a bus of signals, where the bus may have a variety of bit widths.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

The above detailed descriptions of embodiments of the technology are not intended to be exhaustive or to limit the technology to the precise form disclosed above. Although specific embodiments of, and examples for, the technology are described above for illustrative purposes, various equivalent modifications are possible within the scope of the technology, as those skilled in the relevant art will recognize. For example, while steps are presented and/or discussed in a given order, alternative embodiments can perform steps in a different order. Furthermore, the various embodiments described herein can also be combined to provide further embodiments.

From the foregoing, it will be appreciated that specific embodiments of the technology have been described herein for purposes of illustration, but well-known structures and functions have not been shown or described in detail to avoid unnecessarily obscuring the description of the embodiments of the technology. From the foregoing, it will also be appreciated that various modifications can be made without deviating from the technology. For example, various components of the technology can be further divided into subcomponents, or that various components and functions of the technology can be combined and/or integrated. Furthermore, although advantages associated with certain embodiments of the technology have been described in the context of those embodiments, other embodiments can also exhibit such advantages, and not all embodiments need necessarily exhibit such advantages to fall within the scope of the technology. Accordingly, the disclosure and associated technology can encompass other embodiments not expressly shown or described herein.

What is claimed is:

1. A memory device, comprising:
a plurality of command-address input buffers configured to receive a corresponding plurality of command-address signals of a command signal; and
input buffer control circuitry configured to disable one or more command-address input buffers of the plurality of command-address input buffers based at least in part on (i) an operating mode of the memory device and (ii) a memory density of the memory device, a connectivity testmode of the memory device, and/or a mirror function of the memory device.

2. The memory device of claim 1, wherein the one or more command-address input buffers includes (i) a first command-address input buffer configured to receive a first command-address signal of the one or more command-address signals, and (ii) a second command-address input buffer configured to receive a second command-address signal of the one or more command-address signals.

3. The memory device of claim 2, wherein the operating mode of the memory device is an idle (precharge) operating mode, and wherein the input buffer control circuitry is configured to disable the first command-address input buffer and the second command-address input buffer based at least in part on the memory device being outside the idle (precharge) mode of operation.

4. The memory device of claim 3, wherein the input buffer control circuitry is configured to disable the first command-address input buffer and the second command-address input buffer based at least in part on the memory device being outside the idle (precharge) mode of operation while the memory density of the memory device is less than a threshold.

5. The memory device of claim 4, wherein the threshold is 16 Gbit.

6. The memory device of claim 2, wherein the operating mode of the memory device is an idle (precharge) operating mode, and wherein the input buffer control circuitry is configured to disable the first command-address input buffer based at least in part on the memory device being in the idle (precharge) mode of operation while the mirror function of the memory device is enabled.

7. The memory device of claim 6, wherein the input buffer control circuitry is configured to disable the second command-address input buffer based at least in part on the memory device being in the idle (precharge) mode of operation while the mirror function of the memory device is disabled.

8. The memory device of claim 2, wherein the operating mode of the memory device is an idle (precharge) operating mode, and wherein the input buffer control circuitry is configured to disable the first command-address input buffer based at least in part on the memory device being in the idle (precharge) mode of operation while (i) the connectivity testmode of the memory device is disabled and (ii) the mirror function of the memory device is enabled.

9. The memory device of claim 8, wherein the input buffer control circuitry is configured to disable the second command-address input buffer based at least in part on the memory device being in the idle (precharge) mode of operation while (i) the connectivity testmode of the memory device is disabled and (ii) the mirror function of the memory device is disabled.

10. The memory device of claim 2, wherein the input buffer control circuitry is configured to disable the first command-address input buffer and the second command-address input buffer based at least in part on a three-dimensional stack (3DS) mode of the memory device being enabled while a slice identifier received by the input buffer control circuitry does not correspond to the memory device.

11. The memory device of claim 1, wherein the memory device includes a dynamic random-access memory (DRAM) device.

12. The memory device of claim 11, wherein:
the command signal includes first through fourteenth command-address signals CA0-CA13;
the one or more command-address input buffers includes a first command-address input buffer configured to receive the thirteenth command-address signal CA12; and
the one or more command-address input buffers further includes a second command-address input buffer configured to receive the fourteenth command-address signal CA13 of the one or more command-address signals.

13. The memory device of claim 1, wherein the memory device is a planar memory device.

14. The memory device of claim 1, wherein the input buffer control circuitry is configured to disable the one or more command-address input buffers based at least in part on a combination of (i) the operating mode of the memory device and (ii) the memory density of the memory device, the connectivity testmode of the memory device, and/or the mirror function of the memory device, in addition to or instead of a chip select signal CS.

15. A memory device, comprising:
an external terminal configured to receive a first input signal;
an input buffer configured to receive the first input signal via the external terminal; and
input buffer control circuitry configured to selectively disable the input buffer such that a current consumption of the input buffer is reduced, wherein the input buffer control circuitry is configured to selectively disable the input buffer based at least in part on (i) an operating mode of the memory device and (ii) a memory density of the memory device, a connectivity testmode of the memory device, and/or a mirror function of the memory device.

16. The memory device of claim 15, wherein the operating mode of the memory device is an idle (precharge) mode of operation, and wherein the input buffer control circuitry is configured to selectively disable the input buffer based at least in part on the memory device being outside the idle (precharge) mode of operation while the memory density of the memory device is less than a threshold.

17. The memory device of claim 15, wherein the operating mode of the memory device is an idle (precharge) mode of operation, and wherein the input buffer control circuitry is configured to selectively disable the input buffer based at least in part on (a) the memory device being in the idle (precharge) mode of operation while the mirror function of the memory device is disabled, or (b) the memory device being in the idle (precharge) mode of operation while the mirror function of the memory device is enabled.

18. The memory device of claim 15, wherein the input buffer control circuitry is configured to selectively disable the input buffer based at least in part on (a) the connectivity testmode of the memory device being disabled while the mirror function of the memory device is disabled, or (b) the connectivity testmode of the memory device being disabled while the mirror function of the memory device is enabled.

19. A method, comprising:
selectively disabling one or more command-address input buffers of a memory device, wherein the one or more command-address input buffers are configured to receive one or more command-address signals of a command signal, and wherein selectively disabling the one or more command-address input buffers includes selectively disabling individual ones of the one or more command-address input buffers based at least in part on a combination of (i) an operating mode of the memory device and (ii) a memory density of the memory device, a connectivity testmode of the memory device, and/or a mirror function of the memory device.

20. The method of claim 19, wherein the operating mode of the memory device is an idle (precharge) mode of operation, and wherein selectively disabling the one or more command-address input buffers of the memory device includes:
determining that the memory device is outside an idle (precharge) mode of operation while the memory device of the memory device is less than a threshold; or
determining that the memory device is in the idle (precharge) mode of operation while the connectivity testmode of the memory device is disabled.
